(19) United States
(12) Patent Application Publication
(10) Pub. No.: US 2026/0123481 A1
(43) Pub. Date: Apr. 30, 2026

(54) PACKAGE STRUCTURE

(71) Applicant: NEUCHIPS CORPORATION, Hsinchu City (TW)

(72) Inventors: Ling Chieh Li, Hsinchu County (TW); Chih-Wei Chang, Hsinchu City (TW); Hung Lun Lian, Hsinchu County (TW); Chia Chun Chiang, New Taipei City (TW)

(73) Assignee: NEUCHIPS CORPORATION, Hsinchu City (TW)

(21) Appl. No.: 19/044,458

(22) Filed: Feb. 3, 2025

(30) Foreign Application Priority Data
Oct. 28, 2024 (TW) 113141017

(51) Int. Cl. H01L 23/538; H01L 23/31; H01L 25/16; H01L 25/18; H10B 80/00; H10D 80/30

(52) U.S. Cl. CPC H10W 70/65; H10B 80/00; H10W 70/611; H10W 74/141; H10W 90/00; H10D 80/30

(57) ABSTRACT

A package structure includes a substrate, multiple memory chips, and at least one bridge chip. The memory chips are dispersedly disposed in the substrate. The at least one bridge chip is disposed on the substrate, and the memory chips are electrically connected to each other through the at least one bridge chip.

### CROSS-REFERENCE TO RELATED APPLICATION

This application claims the priority benefit of Taiwan application serial no. 113141017, filed on Oct. 28, 2024. The entirety of the above-mentioned patent application is hereby incorporated by reference herein and made a part of this specification.

### BACKGROUND

### Technical Field

The disclosure relates to a semiconductor structure, and particularly relates to a package structure.

### Description of Related Art

In an existing package structure, a bridge chip located in the substrate may bridge multiple memory chips located above the substrate. However, the memory chips above the substrate occupy a larger package space, resulting in a larger package volume of the overall package structure. Furthermore, since the bridge chip is located in the substrate, the electrical transmission paths (including longitudinal transmission and lateral transmission) to the memory chips above the substrate is longer, leading to poorer electrical performance of the package structure.

### SUMMARY

The disclosure provides a package structure that may save package space and may improve electrical performance.

The package structure of the disclosure includes a substrate, multiple memory chips, and at least one bridge chip. The memory chips are dispersedly disposed in the substrate. The at least one bridge chip is disposed on the substrate, and the memory chips are electrically connected to each other through the at least one bridge chip.

In an embodiment of the disclosure, the aforementioned memory chips include a first memory chip and a second memory chip. The at least one bridge chip includes a bridge chip. The first memory chip is electrically connected to the second memory chip through the bridge chip.

In an embodiment of the disclosure, the aforementioned memory chips include a first memory chip, a second memory chip, a third memory chip, and a fourth memory chip. The at least one bridge chip includes a bridge chip. The first memory chip, the second memory chip, the third memory chip, and the fourth memory chip are electrically connected to each other through the bridge chip.

In an embodiment of the disclosure, the aforementioned memory chips include a first memory chip, a second memory chip, a third memory chip, and a fourth memory chip. The at least one bridge chip includes a first bridge chip and a second bridge chip. The first memory chip and the second memory chip are electrically connected to each other through the first bridge chip. The third memory chip and the fourth memory chip are electrically connected to each other through the second bridge chip.

In an embodiment of the disclosure, the aforementioned package structure further includes a connection chip, disposed in the substrate. The first bridge chip is electrically connected to the second bridge chip through the connection chip.

In an embodiment of the disclosure, the aforementioned package structure further includes an encapsulating colloid, disposed on the substrate, and at least encapsulating the at least one bridge chip, while exposing a back side of the at least one bridge chip.

In an embodiment of the disclosure, the aforementioned substrate includes a conductive connection layer. The conductive connection layer is located between the at least one bridge chip and the memory chips, and the memory chips are electrically connected to the at least one bridge chip through the conductive connection layer.

In an embodiment of the disclosure, the material of the aforementioned conductive connection layer may include a semiconductor material, a conductive material, or a combination thereof.

In an embodiment of the disclosure, the aforementioned package structure further includes multiple solder balls. The substrate includes an upper surface and a lower surface opposite to each other. The at least one bridge chip is located on the upper surface, while the solder balls are disposed on the lower surface of the substrate.

In an embodiment of the disclosure, the aforementioned package structure further includes a carrier, including multiple connection pads, and the carrier is electrically connected to the solder balls through the connection pads.

Based on the above, in the package structure of the disclosure, multiple memory chips are dispersedly disposed in a substrate, while a bridge chip is disposed on the substrate, and the memory chips are electrically connected to each other through the bridge chip. By means of the configuration, the package structure of the disclosure may effectively save package space and may improve electrical performance.

In order to make the aforementioned features and advantages of the disclosure comprehensible, embodiments accompanied with drawings are described in detail as follows.

### BRIEF DESCRIPTION OF THE DRAWINGS

FIG. 1 is a cross-sectional schematic diagram of a package structure according to an embodiment of the disclosure.

FIG. 2 is a cross-sectional schematic diagram of a package structure according to another embodiment of the disclosure.

FIG. 3 is a cross-sectional schematic diagram of a package structure according to another embodiment of the disclosure.

FIG. 4 is a cross-sectional schematic diagram of a package structure according to another embodiment of the disclosure.

### DESCRIPTION OF THE EMBODIMENTS

Embodiments of the disclosure may be understood together with drawings, and the drawings of the disclosure are also regarded as a part of description of the disclosure. It should be understood that the drawings of the disclosure are not drawn to scale and, in fact, the dimensions of elements may be arbitrarily enlarged or reduced in order to clearly represent the features of the disclosure.

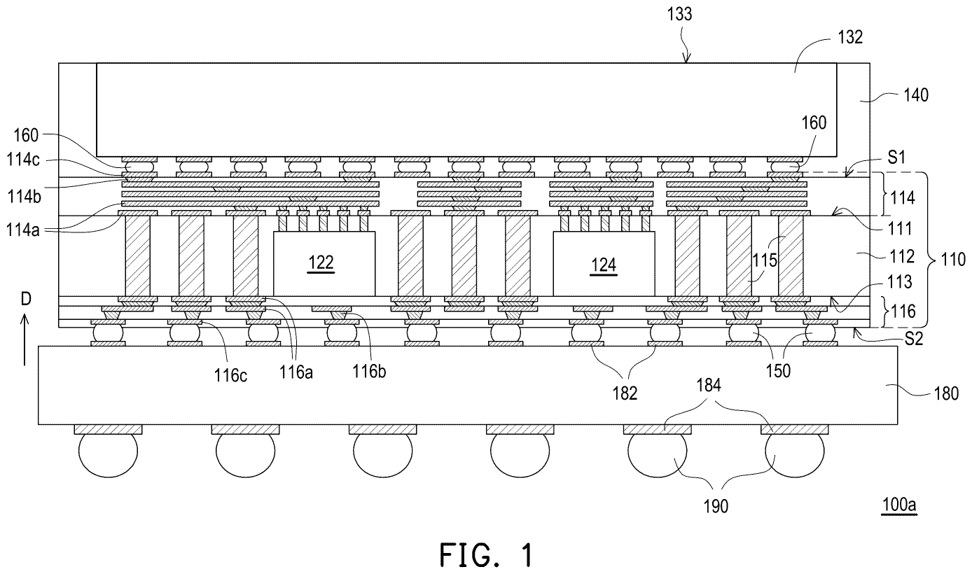

FIG. 1 is a cross-sectional schematic diagram of a package structure according to an embodiment of the disclosure. Referring to FIG. 1, in the embodiment, a package structure 100a includes a substrate 110, multiple memory chips, and at least one bridge chip. The memory chips may include a first memory chip 122 and a second memory chip 124, while the at least one bridge chip includes a bridge chip 132. The first memory chip 122 and the second memory chip 124 are dispersedly disposed in the substrate 110. The bridge chip 132 is disposed on the substrate 110, and the first memory chip 122 and the second memory chip 124 are electrically connected to each other through the bridge chip 132.

In detail, in the embodiment, the substrate 110 has an upper surface S1 and a lower surface S2 opposite to each other, and the bridge chip 132 is located on the upper surface S1. In an embodiment, the substrate 110 may be, for example, a core substrate or a coreless substrate. In the embodiment, the substrate 110 may include a core layer 112 and multiple conductive vias 115 penetrating through the core layer 112. The core layer 112 has a first side 111 and a second side 113 opposite to each other, and the conductive vias 115 penetrate from the first side 111 to the second side 113 of the core layer 112. The core layer 112 may provide rigidity to the substrate 110. In an embodiment, the material of the core layer 112 may be, for example, epoxy resin, polyimide (PI), benzocyclo-butene (BCB), polybenzobisoxazole (PBO), or other suitable dielectric materials.

Moreover, the substrate 110 of the embodiment may include a conductive connection layer 114 disposed on the first side 111 of the core layer 112. The conductive connection layer 114 is located between the bridge chip 132 and the first memory chip 122 and the second memory chip 124, and the first memory chip 122 and the second memory chip 124 are electrically connected to the bridge chip 132 through the conductive connection layer 114. In an embodiment, the conductive connection layer 114 may include alternately stacked dielectric layers and conductive layers, in which the conductive layers may constitute corresponding lines, and the wiring design of the lines may be adjusted according to requirements, which is not limited herein. In an embodiment, the conductive connection layer 114 may include conductive layers 114a, conductive blind vias 114b, and connection pads 114c. Adjacent conductive layers 114a may be electrically connected through the conductive blind vias 114b, and the connection pads 114c may be located on the upper surface S1 of the substrate 110. In an embodiment, the unconnected parts of the conductive connection layer 114 in the figure may be electrically connected by means of other unillustrated parts and/or other conductive elements. In an embodiment, the material of the conductive connection layer 114 may be, for example, a semiconductor material, a conductive material, or a combination thereof. In an embodiment, the conductive layers 114a and connection pads 114c may be, for example, one layer or multiple layers, and the material thereof may include metal, metal alloy, and/or other metal-containing compounds, but is not limited thereto.

Moreover, the substrate 110 of the embodiment may further include a line structure layer 116, disposed on the second side 113 of the core layer 112. The conductive vias 115 electrically connect the conductive connection layer 114 and the line structure layer 116. In an embodiment, the line structure layer 116 may include alternately stacked dielectric layers and line layers, in which the line layers may constitute corresponding lines, and the wiring design of the lines may be adjusted according to requirements, which is not limited herein. In an embodiment, the line structure layer 116 may include line layers 116a, conductive blind vias 116b, and connection pads 116c. Adjacent line layers 116a may be electrically connected through the conductive blind vias 116b, and the connection pads 116c are adjacent to the lower surface S2 of the substrate 110. In an embodiment, the line layers 116a and connection pads 116c may be, for example, one layer or multiple layers, and the material thereof may include metal, metal alloy, and/or other metal-containing compounds, but is not limited thereto. In an embodiment, the number of layers of the line layers 116a in the line structure layer 116 may be less than the number of layers of the conductive layers 114a in the conductive connection layer 114, but is not limited thereto. In an embodiment, the number of layers of the line layers 116a in the line structure layer 116 is, for example, three layers, while the number of layers of the conductive layers 114a in the conductive connection layer 114 is, for example, five layers. In an embodiment, the number of layers of the line layers 116a in the line structure layer 116 may be greater than or equal to the number of layers of the conductive layers 114a in the conductive connection layer 114, but is not limited thereto.

Please refer again to FIG. 1, in cross-section view, along a direction D (for example, the normal direction of the substrate 110), the bridge chip 132 is located above the first memory chip 122 and the second memory chip 124, in which the first memory chip 122 is electrically connected to the second memory chip 124 through the bridge chip 132. In other words, the first memory chip 122 and the second memory chip 124 do not have bridging functionality and need to be bridged to each other through the bridge chip 132. One bridge chip 132 may connect two memory chips (i.e., the first memory chip 122 and the second memory chip 124). That is to say, the quantity of bridge chips is less than the quantity of memory chips.

In an embodiment, the bridge chip 132 may be electrically connected to the connection pads 114c of the conductive connection layer 114 through connection members 160, in which the connection members 160 may be, for example, solder balls, metal pillars, Controlled Collapse Chip Connection (C4) bumps, or micro bumps, but is not limited thereto. In an embodiment, the bridge chip 132 may be bonded to the first memory chip 122 and the second memory chip 124 by means of hybrid bonding (i.e., direct bonding that may include dielectric-to-dielectric bond, polymer-to-polymer bond, and/or metal-to-metal bond).

In an embodiment, the bridge chip 132 may be, for example, a logic chip, a central processing unit (CPU) chip, a graphics processing unit (GPU) chip, a field-programmable gate array (FPGA) chip, a network connection chip, an application-specific integrated circuit (ASIC) chip, an artificial intelligence/deep neural network (AI/DNN) accelerator chip, a co-processor, an accelerator, a high data rate transceiver chip, an I/O interface chip, an integrated passives device (IPD) chip (for example, integrated passive devices), a power management chip (for example, a power management integrated circuit (PMIC) chip), a radio frequency (RF) chip, a sensor chip, a micro-electro-mechanical-system (MEMS) chip, a signal processing chip (for example, a digital signal processing (DSP) chip), a front-end chip (for example, an analog front-end (AFE) chip), a monolithic 3D heterogeneous chiplet stack chip or a Neural processing unit, but is not limited thereto. In an embodiment, the first memory chip 122 and the second memory chip 124 may be, for example, static random access memory (SRAM), magnetoresistive random access memory (MRAM), dynamic random access memory (DRAM), high bandwidth memory (HBM), back-end-of-line (BEOL) type memory and/or any other suitable memory chip, respectively.

Moreover, the package structure 100a of the embodiment further includes an encapsulating colloid 140, disposed on the substrate 110, and at least encapsulating the bridge chip 132, while exposing a back surface 133 of the bridge chip 132, which helps to improve the heat dissipation effect of the package structure 100a. In an embodiment, the material of the encapsulating colloid 140 may be, for example, Epoxy Molding Compound (EMC), in which the encapsulating colloid 140 may be formed by means of a molding process, but is not limited thereto.

In addition, the package structure 100a of the embodiment further includes multiple solder balls 150, disposed on the lower surface S2 of the substrate 110, in which the solder balls 150 contact the connection pads 116c of the line structure layer 116 respectively through openings on the lower surface S2 of the substrate 110. Moreover, the package structure 100a of the embodiment may further include a carrier 180, including multiple connection pads 182 adjacent to the substrate 110 and multiple connection pads 184 relatively far from the substrate 110. The carrier 180 is electrically connected to the solder balls 150 through the connection pads 182. Here, the dimension of the carrier 180 may be larger than the dimension of the substrate 110, in which the carrier 180 may be, for example, a build-up film substrate (for example, an Ajinomoto build-up film (ABF) substrate), but is not limited thereto. Furthermore, the package structure 100a of the embodiment may further include multiple solder balls 190, disposed on another side of the carrier 180 relatively far from the substrate 110, and electrically connected to the connection pads 184 of the carrier 180, and the package structure 100a may be electrically connected to an external circuit (for example, a printed circuit board (PCB)) through the solder balls 190. In an embodiment, the dimension of the solder balls 190 is larger than the dimension of the solder balls 150.

In brief, the embodiment achieves effective saving of package space in the package structure 100a by means of disposing the first memory chip 122 and the second memory chip 124 in the substrate 110. Moreover, by using the bridge chip 132 located on the substrate 110 to bridge the first memory chip 122 and the second memory chip 124 located in the substrate 110, the electrical path between the bridge chip 132 and the first memory chip 122 and the second memory chip 124 is shorter, thereby realizing rapid transmission of electrical signals, which may improve the electrical performance of the package structure 100a.

It must be noted here that the following embodiments use the element numerals and part of the contents of the foregoing embodiments, the same numerals are used to denote the same or similar elements, and the description of the same technical content is omitted. For the description of the omitted parts, reference may be made to the foregoing embodiments, and thus the description is not repeated in the following embodiments.

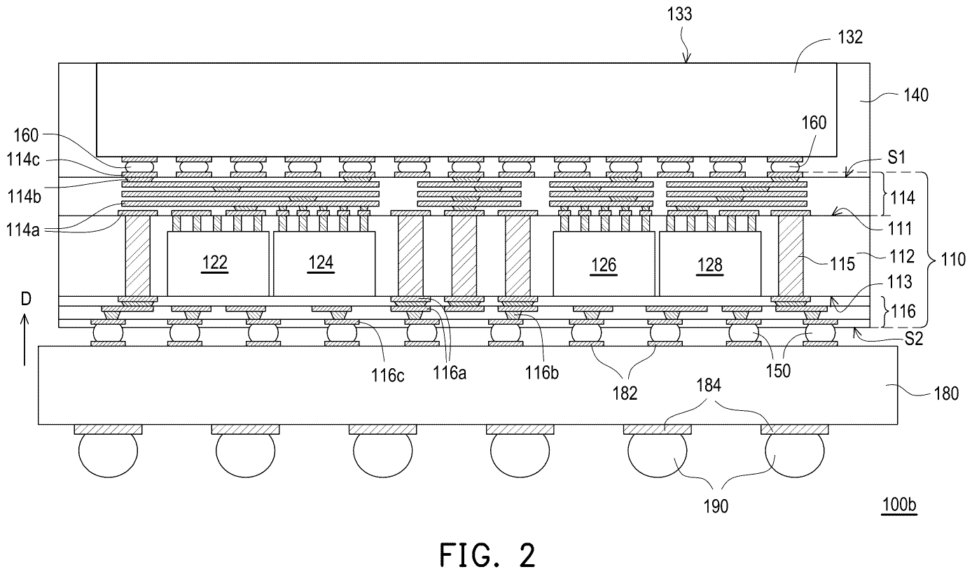

FIG. 2 is a cross-sectional schematic diagram of a package structure according to another embodiment of the disclosure. Please refer to FIG. 1 and FIG. 2 at the same time. A package structure 100b of the embodiment is similar to the aforementioned package structure 100a, but the main difference between the two is: in the embodiment, the memory chips include the first memory chip 122, the second memory chip 124, a third memory chip 126, and a fourth memory chip 128. The at least one bridge chip includes the bridge chip 132. The first memory chip 122, the second memory chip 124, the third memory chip 126, and the fourth memory chip 128 are electrically connected to each other through the bridge chip 132. In other words, one bridge chip 132 may connect four memory chips (i.e., the first memory chip 122, the second memory chip 124, the third memory chip 126, and the fourth memory chip 128).

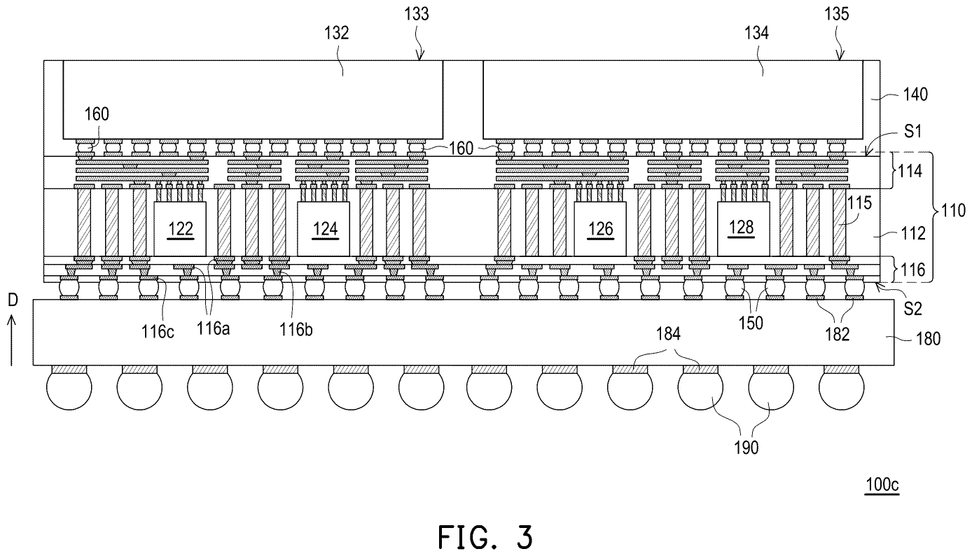

FIG. 3 is a cross-sectional schematic diagram of a package structure according to another embodiment of the disclosure. Please refer to FIG. 1 and FIG. 3 at the same time. A package structure 100c of the embodiment is similar to the aforementioned package structure 100a, but the main difference between the two is: in the embodiment, the memory chips include the first memory chip 122, the second memory chip 124, the third memory chip 126, and the fourth memory chip 128. The at least one bridge chip includes the first bridge chip 132 and a second bridge chip 134. The first memory chip 122 and the second memory chip 124 are electrically connected to each other through the first bridge chip 132. The third memory chip 126 and the fourth memory chip 128 are electrically connected to each other through the second bridge chip 134. In other words, the package structure 100c of the embodiment may include multiple bridge chips, and each of the bridge chips may connect two memory chips.

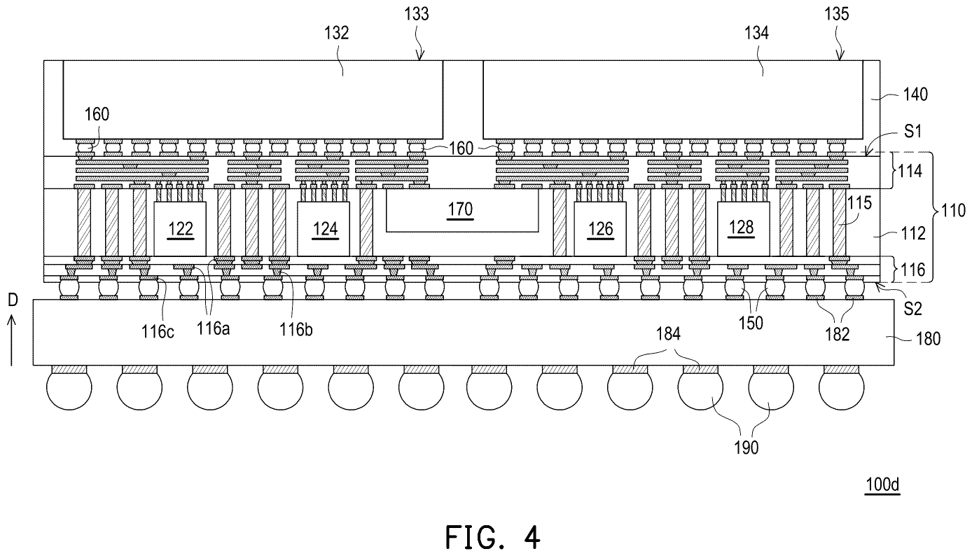

FIG. 4 is a cross-sectional schematic diagram of a package structure according to another embodiment of the disclosure. Please refer to FIG. 3 and FIG. 4 at the same time. A package structure 100d of the embodiment is similar to the aforementioned package structure 100c, but the main difference between the two is: in the embodiment, the package structure 100d further includes a connection chip 170, disposed in the substrate 110, in which the first bridge chip 132 and the second bridge chip 134 are electrically connected to each other through the connection chip 170. In an embodiment, the connection chip 170 may be located within the core layer 112 of the substrate 110.

It is worth mentioning that the dimensions of the bridge chip, memory chip, and connection chip in the embodiment are merely illustrative and are not intended to limit the disclosure. Furthermore, the quantity of bridge chips and memory chips in the embodiment is merely illustrative and is not intended to limit the disclosure. As long as the quantity of bridge chips is less than the quantity of memory chips, it falls within the scope of protection sought by the disclosure.

In summary, in the package structure of the disclosure, multiple memory chips are dispersedly disposed in a substrate, while a bridge chip is disposed on the substrate, and the memory chips are electrically connected to each other through the bridge chip. By means of the configuration, the package structure of the disclosure may effectively save package space and may improve electrical performance.

Although the disclosure has been described with reference to the above embodiments, the described embodiments are not intended to limit the disclosure. People of ordinary skill in the art may make some changes and modifications without departing from the spirit and the scope of the disclosure. Thus, the scope of the disclosure shall be subject to those defined by the attached claims.

What is claimed is:

1. A package structure, comprising:
a substrate;
a plurality of memory chips, dispersedly disposed in the substrate; and
at least one bridge chip, disposed on the substrate, wherein the memory chips are electrically connected to each other through the at least one bridge chip.

2. The package structure according to claim 1, wherein the memory chips comprise a first memory chip and a second memory chip, the at least one bridge chip comprises a bridge chip, and the first memory chip is electrically connected to the second memory chip through the bridge chip.

3. The package structure according to claim 1, wherein the memory chips comprise a first memory chip, a second memory chip, a third memory chip, and a fourth memory chip, the at least one bridge chip comprises a bridge chip, and the first memory chip, the second memory chip, the third memory chip, and the fourth memory chip are electrically connected to each other through the bridge chip.

4. The package structure according to claim 1, wherein the memory chips comprise a first memory chip, a second memory chip, a third memory chip, and a fourth memory chip, the at least one bridge chip comprises a first bridge chip and a second bridge chip, the first memory chip and the second memory chip are electrically connected to each other through the first bridge chip, and the third memory chip and the fourth memory chip are electrically connected to each other through the second bridge chip.

5. The package structure according to claim 4, further comprising:
a connection chip, disposed in the substrate, wherein the first bridge chip is electrically connected to the second bridge chip through the connection chip.

6. The package structure according to claim 1, further comprising:
an encapsulating colloid, disposed on the substrate, and at least encapsulating the at least one bridge chip, while exposing a back side of the at least one bridge chip.

7. The package structure according to claim 1, wherein the substrate comprises a conductive connection layer, the conductive connection layer is located between the at least one bridge chip and the memory chips, and the memory chips are electrically connected to the at least one bridge chip through the conductive connection layer.

8. The package structure according to claim 7, wherein a material of the conductive connection layer comprises a semiconductor material, a conductive material or a combination thereof.

9. The package structure according to claim 1, further comprising:
a plurality of solder balls, the substrate comprising an upper surface and a lower surface opposite to each other, and the at least one bridge chip being located on the upper surface, while the solder balls being disposed on the lower surface of the substrate.

10. The package structure according to claim 9, further comprising:
a carrier, comprising a plurality of connection pads, and the carrier being electrically connected to the solder balls through the connection pads.
